(19) United States
(12) Patent Application Publication
(10) Pub. No.: US 2025/0234575 A1
(43) Pub. Date: Jul. 17, 2025

(54) SEMICONDUCTOR DEVICE AND MANUFACTURING METHOD THEREOF

(71) Applicant: United Microelectronics Corp., Hsinchu (TW)

(72) Inventors: Hsin-Hsien Chen, New Taipei City (TW); Kuo-Hsing Lee, Hsinchu County (TW)

(73) Assignee: United Microelectronics Corp., Hsinchu (TW)

(21) Appl. No.: 18/596,631

(22) Filed: Mar. 6, 2024

(30) Foreign Application Priority Data
Jan. 15, 2024 (TW) 113101537

(51) Int. Cl. H01L 29/66; H01L 21/8234; H01L 27/06; H01L 27/088; H01L 29/417; H01L 29/78; H01L 29/94

(52) U.S. Cl. CPC H10D 30/024; H10D 1/66; H10D 30/62; H10D 30/6219; H10D 64/017; H10D 84/0158; H10D 84/038; H10D 84/811; H10D 84/834

(57) ABSTRACT

A semiconductor device including a substrate, a fin, a gate structure, a single diffusion break (SDB) structure and a capacitor gate structure. The substrate has a first region and a second region, wherein the second region is located between the adjacent first regions. The fin is disposed on the substrate, wherein the fin located in the second region includes a heavily doped region. The gate structure is disposed on the fin and located in the first region. The SDB structure is disposed on the fin and located in the second region. The capacitor gate structure is disposed on the fin and is located in the second region, wherein the capacitor gate structure is disposed on the SDB structure. A manufacturing method of a semiconductor device is also provided.

### CROSS-REFERENCE TO RELATED APPLICATION

This application claims the priority benefit of Taiwan application serial no. 113101537, filed on Jan. 15, 2024. The entirety of the above-mentioned patent application is hereby incorporated by reference herein and made a part of specification.

### BACKGROUND

### Technical Field

The disclosure relates to a semiconductor device and a manufacturing method thereof, and in particular to a fin field-effect transistor (FinFET) device including a metal-oxide-semiconductor capacitor and a manufacturing method thereof.

### Description of Related Art

In recent years, the size of semiconductor device is gradually scaled, in which the technologies of replacing the planar transistor device with the FinFET device have been proposed. In order to continue to increase the integration, density and performance of semiconductor device, it is still necessary to further improve the electrical performance and process yield of fin field-effect transistor device through the process and/or the structural design.

For example, when a metal-oxide-semiconductor capacitor (MOSCAP) is applied to the structure of the FinFET device, a heavily doped region should be doped in fins of the FinFET device to have high conductivity. However, when an oxide layer is subsequently grown on the fins by performing a thermal oxidation process, the fins including the heavily doped regions would consume too much during the growth of the oxide layer, causing a top of the fins to be tapered after the oxide layer is grown. Therefore, the reliability of the manufactured semiconductor device is reduced.

Furthermore, the region in the FinFET device used for the transistor would be limited due to the formation of the MOSCAP.

### SUMMARY

The disclosure provides a semiconductor device having the effects of high integration, high density and high performance, and could have relatively good reliability.

According to some embodiments of the disclosure, a semiconductor device including a substrate, a fin, a gate structure, a single diffusion break (SDB) structure and a capacitor gate structure. The substrate has a first region and a second region, wherein the second region Is located between the adjacent first regions. The fin is disposed on the substrate, wherein the fin located in the second region includes a heavily doped region. The gate structure is disposed on the fin and located in the first region. The SDB structure is disposed on the fin and located in the second region. The capacitor gate structure is disposed on the fin and is located in the second region, wherein the capacitor gate structure is disposed on the SDB structure.

The disclosure also provides a manufacturing method of a semiconductor device. The manufactured semiconductor device has the effects of high integration, high density and high performance, and could have relatively good reliability.

According to some embodiments of the disclosure, the manufacturing method of the semiconductor device includes the following steps. First, forming a fin on a substrate, wherein the fin spans a first region and a second region of the substrate, and the second region is located between adjacent first regions. Next, forming a single diffusion break (SDB) structure in the second region of the substrate, wherein an extension direction of the SDB structure is perpendicular to an extension direction of the fin, and the SDB structure spans the fin. After that, forming a heavily doped region in the fin located in the second region. Then, respectively forming a gate structure and a capacitor gate structure on the fin located in the first region and the second region of the substrate, wherein the capacitor gate structure is disposed on the SDB structure.

Based on the above, in the semiconductor device and the manufacturing method thereof provided by the disclosure, the area of the first region for forming the gate structure could not be reduced by forming the capacitor gate structure in the second region of the substrate, so that the semiconductor device provided by the disclosure could have better effects, such as high integration, high density, and high performance. Furthermore, the capacitor gate structure formed in the second region of the substrate is disposed on the SDB structure. Therefore, the tapering phenomenon on the top of the fin in the second region due to the formation of the heavily doped region could be slowed down, so that the semiconductor device provided by the disclosure could have relatively good reliability.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a partial top view of a semiconductor device according to an embodiment of the disclosure.

FIG. 1B is a partial cross-sectional schematic diagram taken along a cross-section line A-A′ of FIG. 1A.

FIG. 1C is a partial cross-sectional schematic diagram taken along a cross-section line B-B′ of FIG. 1A.

FIG. 2 is a schematic flowchart of a manufacturing method of a semiconductor device according to an embodiment of the disclosure.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

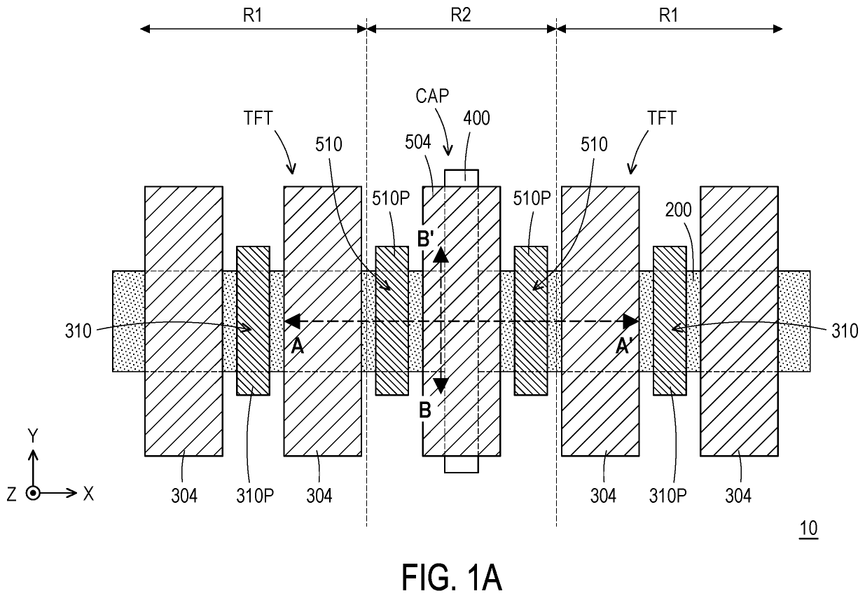

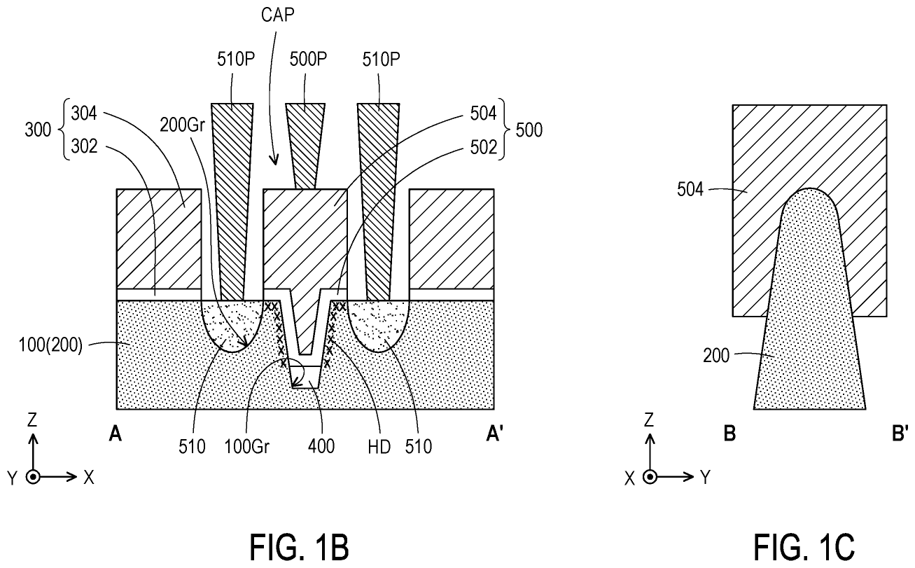

FIG. 1A is a partial top view of a semiconductor device according to an embodiment of the disclosure, FIG. 1B is a partial cross-sectional schematic diagram taken along a cross-section line A-A′ of FIG. 1A, and FIG. 1C is a partial cross-sectional schematic diagram taken along a cross-section line B-B′ of FIG. 1A.

Referring to FIGS. 1A-1C, which show a semiconductor device 10 provided by the present embodiment. In the present embodiment, the semiconductor device 10 includes a substrate 100, a fin 200, a gate structure 300, a single diffusion break (SDB) structure 400 and a capacitor gate structure 500.

A material of the substrate 100 includes element semiconductors, compound semiconductors, alloy semiconductors or other suitable materials. For example, the substrate 100 could be a silicon substrate or a silicon on insulator (SOI) substrate, but the disclosure is not limited thereto.

The substrate 100 includes a first region R1 and a second region R2, wherein the second region R2 is located between the adjacent first regions R1. The first region R1 is a transistor region, on which a fin field-effect transistor (FinFET) that would be introduced later is disposed. The second region R2 is a capacitor region, which was originally a dummy region located between the adjacent transistor regions, on which a metal-oxide-semiconductor capacitor (MOSCAP) that would be introduced later is disposed.

In the present embodiment, the second region R2 of the substrate 100 includes a heavily doped region HD. The doping ions in the heavily doped region HD could be N-type ions. For example, the doping ions in the heavily doped region HD include phosphorus ions or arsenic ions, but the disclosure is not limited thereto. By forming the heavily doped region HD in the second region R2 of the substrate 100, in which the conductivity could be increased, so that the heavily doped region HD could be used as a terminal of the MOSCAP.

The fin 200 is disposed on the substrate 100. In some embodiments, the fin 200 extends along a direction X to span the first region R1 and the second region R2 of the substrate 100. It is worth noting that the number of fin 200 is not limited by the partial top view shown in FIG. 1. In detail, the semiconductor device 10 includes a plurality of the fins 200, wherein the plurality of fins 200 have a specific distance from each other and extend along the direction X.

The gate structure 300 is disposed on the fin 200. In some embodiments, the gate structure 300 extends along a direction Y, which is perpendicular to the direction X. In the present embodiment, the gate structure 300 is located in the first region R1 of the substrate 100. Therefore, the gate structure 300 could span the fin 200 located in the first region R1 of the substrate 100.

In some embodiments, the gate structure 300 includes a gate dielectric layer 302 and a gate 304. The gate dielectric layer 302 is disposed on the fin 200. In some embodiments, a material of the gate dielectric layer 302 includes silicon oxide, silicon nitride, silicon oxynitride, or a combination thereof, but the disclosure is not limited thereto. In other embodiments, the material of the gate dielectric layer 302 includes a material having a high dielectric constant, which could include hafnium dioxide, zirconium dioxide, or other suitable materials. The gate 304 is disposed on the gate dielectric layer 302. In some embodiments, a material of the gate 304 includes polycrystalline silicon or amorphous silicon, but the disclosure is not limited thereto.

In some embodiments, a source/drain region 310 is disposed in the fin 200 on one side of the gate structure 300. The source/drain region 310 could include an epitaxial layer. In some embodiments, a material of the epitaxial layer includes silicon phosphide or silicon carbide, but the disclosure is not limited thereto. In other embodiments, the material of the epitaxial layer includes silicon germanium.

Based on the above, the semiconductor device 10 of the present embodiment includes a fin field-effect transistor TFT, which includes the above gate structure 300 and the source/drain region 310, in which the fin 200 covered by the gate structure 300 serves as a channel region of the fin field-effect transistor TFT.

In addition, in some embodiments, a contact plug 310P is disposed on the source/drain region 310 of the fin field-effect transistor TFT and is electrically connected to the fin field-effect transistor TFT, wherein the contact plug 310P extends along a direction Z. The contact plug 310P could include a barrier layer (not shown) and a metal layer (not shown), wherein a material of the barrier layer includes titanium, titanium nitride, tantalum, tantalum nitride, or a combination thereof, and a material of the metal layer includes tungsten, copper, aluminum, titanium-aluminum alloy, or a combination thereof, but the disclosure is not limited thereto.

The SDB structure 400 is disposed on the fin 200. In some embodiments, the SDB structure 400 extends along the direction Y and is located in the second region R2 of the substrate 100. The SDB structure 400 could separate the fin 200 into two parts. In detail, the substrate 100 includes a groove 100Gr located in the second region R2 and extending along the direction Y, wherein the fin 200 extending along the direction X are separated by the groove 100Gr, and the SDB structure 400 is disposed in the groove 100Gr. In some embodiments, a material of the SDB structure 400 includes silicon oxide, but the disclosure is not limited thereto. In other embodiments, a material of the SDB structure 400 includes silicon nitride, silicon oxynitride, or a combination thereof.

The capacitor gate structure 500 is disposed on the fin 200. In some embodiments, the capacitor gate structure 500 extends along the direction Y. In the present embodiment, the capacitor gate structure 500 is located in the second region R2 of the substrate 100. Therefore, the capacitor gate structure 500 could span the fin 200 located in the second region R2 of the substrate 100.

In some embodiments, the capacitor gate structure 500 includes a capacitor dielectric layer 502 and a capacitor gate 504. The capacitor dielectric layer 502 is disposed on the fin 200. In some embodiments, a material of the capacitor dielectric layer 502 could be the same as or similar to the material of the gate dielectric layer 302, and would be omitted herein. The capacitor gate 504 is disposed on the capacitor dielectric layer 502. In some embodiments, a material of the capacitor gate 504 could be the same or similar to the material of the gate 304, and would be omitted herein.

The capacitor gate structure 500 is disposed on the SDB structure 400. In the present embodiment, the capacitor gate structure 500 partially overlaps the SDB structure 400. In detail, the capacitor gate structure 500 partially overlaps the SDB structure 400 in the direction Z, and a width of the capacitor gate structure 500 in the direction X is greater than a width of the SDB structure 400 in the direction X. Therefore, a portion of the capacitor gate structure 500 could be disposed between the segmented fin 200.

In some embodiments, a dummy source/drain region 510 is disposed in the fin 200 on both sides of the capacitor gate structure 500. A material of the dummy source/drain region 510 could be the same as or similar to the material of the source/drain region 310, and would be omitted herein.

Based on the above, the semiconductor device 10 of the present embodiment includes a capacitor CAP, which includes the capacitor gate 504, the capacitor dielectric layer 502, the heavily doped region HD located in the fin 200, and the dummy source/drain region 510. The capacitor gate 504 serves as one terminal of the capacitor CAP, and the heavily doped region HD and the dummy source/drain region 510 serve as the other terminal of the capacitor CAP. Namely, the capacitor CAP in the present embodiment is a MOSCAP.

In addition, in some embodiments, a contact plug 500P is disposed on the capacitor gate structure 500 of the capacitor CAP and is electrically connected to the capacitor CAP, and a contact plug 510P is disposed on the dummy source/drain region 510 of the capacitor CAP and is electrically connected to the capacitor CAP, wherein the contact plug 500P and the contact plug 510P extend along the direction Z. A material of the contact plug 500P and a material of the contact plug 510P could be the same or similar to the material of the contact plug 310P, and would be omitted herein.

Based on the above, by disposing the capacitor CAP in the second region R2 of the substrate 100, the second region R2 originally used as the dummy region could be effectively utilized. Therefore, the capacitor CAP could be provided without reducing a number of the components originally disposed in the first region R1 of the substrate 100, so that the semiconductor device 10 of the present embodiment could have high integration, high density, and high performance.

Furthermore, as shown in FIG. 1C, the tapering phenomenon on the top of the fin 200 in the second region R2 due to the formation of the heavily doped region HD could be slowed down since the SDB structure 400 is located in the second region R2 of the substrate 100, so that the semiconductor device 10 of the present embodiment could have relatively good reliability.

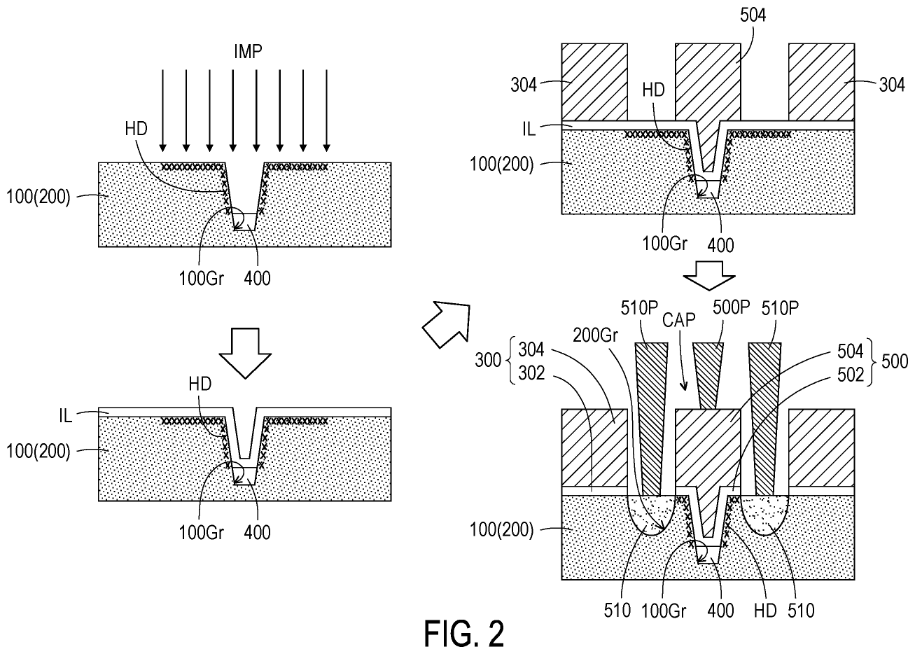

FIG. 2 is a schematic flowchart of a manufacturing method of a semiconductor device according to an embodiment of the disclosure. It should be noted that the embodiment of FIG. 2 could use the reference numbers and portions of the content of the above embodiments of FIGS. 1A-1C, wherein the same or similar reference numbers are used to represent the same or similar elements, and descriptions of the same technical contents are omitted.

First, forming a fin 200 on a substrate 100. The substrate 100 includes a first region R1 and a second region R2, wherein the first region R1 is defined as a transistor region, and the second region R2 is defined as a capacitor region. It is worth noting that the rest of the introduction pertaining the substrate 100 could refer to the above embodiments, and would be omitted herein.

The fin 200 spans the first region R1 and the second region R2 of the substrate 100. In some embodiments, the fin 200 could be manufactured by performing a sidewall image transfer (SIT) process, and could be formed by performing the following process, but the disclosure is not limited thereto. Step (1): Provide a layout pattern to a computer system, and perform appropriate calculations to define the corresponding pattern in a photomask. Step (2): Performing a photolithography process and an etching process to form a plurality of patterned sacrificial layers (not shown) equidistant and having equal widths on the substrate 100, so that the appearance of the patterned sacrificial layers appears in a strip shape. Step (3): Performing a deposition process and an etching process to form spacers (not shown) on each sidewall of the patterned sacrificial layers. Step (4): Removing the patterned sacrificial layers, and performing an etching process through the coverage of the spacers, so that a pattern formed by the spacers is transferred to the substrate 100. Step (5): Performing a cutting process on the substrate 100 to obtain the required patterned structure, such as the strip patterned fins 200 shown in FIG. 1A.

In other embodiments, the fin 200 could be formed by performing the following process. Step (1): Forming a patterned mask (not shown) on the substrate 100. Step (2): Using the patterned mask to perform an etching process on the substrate 100 to form the fin 200.

In some embodiments, the fin 200 could be formed by performing the following process. Step (1): Forming a patterned mask (not shown) on the substrate 100. Step (2): Using the patterned mask to perform an epitaxial process on the substrate 100 to grow a semiconductor layer (such as silicon germanium) on the substrate 100, and the semiconductor layer serves as the corresponding fin 200.

Next, forming a single diffusion break (SDB) structure 400 in the second region R2 of the substrate 100, wherein an extension direction of the SDB structure 400 is perpendicular to an extension direction of the fin 200, and the SDB structure 400 spans the fin 200. Based on the above, the SDB structure 400 could separate the fin 200 into two parts.

The SDB structure 400 could be formed by performing the following process, but the disclosure is not limited thereto. Step (1): Forming a patterned mask (not shown) on the substrate 100, wherein the patterned mask covers the first region R1 of the substrate 100. Step (2): Using the patterned mask to perform an etching process on the fin 200 and the substrate 100, to remove a portion of the fin 200 located in the second region R2, and further remove a portion of the substrate 100 located below the original fin 200 to form a groove 100Gr, which separates the fin 200 into two parts. Step (3): Forming a dielectric layer in the groove 100Gr to form the SDB structure 400, wherein a top surface of the SDB structure 400 is lower than a top surface of the fin 200.

The dielectric layer disposed in the groove 100Gr could be formed by performing the following process, but the disclosure is not limited thereto. Step (3-1): Filling the groove 100Gr with a dielectric layer. Step (3-2): Performing an etch-back process to remove a portion of the dielectric layer in the groove 100Gr, so that the top surface of the etched SDB structure 400 is lower than the top surface of the fin 200.

In some embodiments, before forming the SDB structure 400 in the second region R2 of the substrate 100, a shallow trench isolation structure (not shown) could be formed in the first region R1 of the substrate 100, wherein the shallow trench isolation structure surrounds the fin 200. A method of forming the shallow trench isolation structure includes performing a flowable chemical vapor deposition (FCVD) process to form a silicon oxide layer covering the fin 200 on the substrate 100, and then performing a chemical mechanical polishing (CMP) process and/or an etching process to remove a portion of the silicon oxide layer.

Then, forming a heavily doped region HD in the second region R2 of the substrate 100. The heavily doped region HD could be formed by performing the following process, but the disclosure is not limited thereto. Step (1): Forming a patterned mask (not shown) on the substrate 100, wherein the patterned mask covers the first region R1 of the substrate 100. Step (2): Performing an ion implantation process IMP by using the patterned mask to ionize the second region R2 of the substrate 100. Step (3): Performing a rapid thermal processing (RTP) on the substrate 100 to form the heavily doped region HD in the second region R2 of the substrate 100. In some embodiments, the implanted doping ions in the ion implantation process IMP are N-type ions, which could include phosphorus ions or arsenic ions, but the disclosure is not limited thereto. By forming the heavily doped region HD in the second region R2 of the substrate 100, in which the conductivity could be increased, so that the heavily doped region HD could be used as a terminal of a capacitor.

It is worth noting that the fin 200 located in the second region R2 of the substrate 100 is more amorphous than the fin 200 located in the first region R1 of the substrate 100 since the heavily doped region HD is formed in the second region R2 of the substrate 100 to make the second region R2 have a relatively high doping concentration. In this case, when the substrate 100 is subjected to the RTP process and/or a thermal oxidation process to form a dielectric layer IL that would be introduced later, the fin 200 located in the second region R2 of the substrate 100 would be consumed at a faster rate than the fin 200 located in the first region R1 of the substrate 100.

In this regard, since the SDB structure 400 is formed in the second region R2 of the substrate 100, the tapering phenomenon on the top of the fin 200 in the second region R2 due to the formation of the heavily doped region HD could be slowed down, so that the semiconductor device 10 could have relatively good reliability.

After that, respectively forming a gate structure 300 and a capacitor gate structure 500 on the fin 200 located in the first region R1 and the second region R2. In some embodiments, the gate structure 300 and the capacitor gate structure 500 could be manufactured by performing a gate first process or a gate last process in accordance with the process requirements, but the disclosure is not limited thereto.

The gate structure 300 and the capacitor gate structure 500 could be formed by performing the following process, but the disclosure is not limited thereto. Step (1): Performing a thermal oxidation process or a deposition process to form the dielectric layer IL on the substrate 100. Step (2): Performing a deposition process to form a gate material layer (not shown) on the dielectric layer IL, wherein the deposition process could include a chemical vapor deposition (CVD), a physical vapor deposition (PVD) or an atomic layer deposition (ALD). Step (3):

Performing a patterning process on the substrate 100 to remove a portion of the dielectric layer IL and a portion of the gate material layer once or successively to form a gate dielectric layer 302 and a gate 304 in the first region R1, and form a capacitor dielectric layer 502 and a capacitor gate 504 in the second region R2.

It is worth noting that the rest of the introduction pertaining the gate structure 300 and the capacitor gate structure 500 could refer to the above embodiments, and would be omitted herein.

Next, respectively forming a source/drain region 310 and a dummy source/drain region 510 in the fin 200 located in the first region R1 and the second region R2. The source/drain region 310 and the dummy source/drain region 510 could be formed by performing the following process, but the disclosure is not limited thereto. Step (1): Performing an etching process on the fin 200 located in the first region R1 and the second region R2 of the substrate 100 to form a recess 200Gr by respectively using the gate structure 300 and the capacitor gate structure 500 as masks, wherein the additional mask could be used in the etching process, but the disclosure is not limited thereto. Step (2): Performing an epitaxial growth process to form an epitaxial layer in the recess 200Gr of the fin 200, wherein the epitaxial layer located in the first region R1 of the substrate 100 could be used as the source/drain region 310, the epitaxial layer located in the second region R2 of the substrate 100 could be used as the dummy source/drain region 510.

After forming the source/drain region 310 and the dummy source/drain region 510, a fin field-effect transistor TFT and a capacitor CAP are formed, respectively. The fin field-effect transistor TFT includes the gate structure 300 and the source/drain region 310, wherein the fin 200 covered by the gate structure 300 serves as a channel region of the fin field-effect transistor TFT.

The capacitor CAP includes the capacitor gate 504, the capacitor dielectric layer 502, the heavily doped region HD located in the fin 200, and the dummy source/drain region 510, wherein the capacitor gate 504 serves as a terminal of the capacitor CAP, and the heavily doped region HD and the dummy source/drain region 510 serve as the other terminal of the capacitor CAP. Namely, the capacitor CAP in the present embodiment is a MOSCAP.

After that, respectively forming a contact plug 500P and a contact plug 510P on the capacitor gate structure 500 and the dummy source/drain region 510 of the capacitor CAP. The rest of the introduction pertaining the contact plug 500P and the contact plug 510P could refer to the above embodiments, and would be omitted herein.

At this point, the manufacturing method of the semiconductor device 10 is completed. Although the manufacturing method of the semiconductor device 10 in the present embodiment is described by taking the above method as an example, the manufacturing method of the semiconductor device provided by the disclosure is not limited thereto. It is worth noting that the semiconductor device 10 of the present embodiment is a fin field-effect transistor device including the MOSCAP, but the semiconductor device provided by the disclosure is not limited thereto.

In summary, in the semiconductor device and the manufacturing method thereof provided by the disclosure, the area of the first region for forming the gate structure could not be reduced by forming the capacitor gate structure in the second region (the original dummy region) of the substrate, so that the semiconductor device provided by the disclosure could have better effects, such as high integration, high density, and high performance. Furthermore, the capacitor gate structure formed in the second region of the substrate is disposed on the SDB structure. Therefore, the tapering phenomenon on the top of the fin in the second region due to the formation of the heavily doped region could be slowed down, so that the semiconductor device provided by the disclosure could have relatively good reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, including:
a substrate, having a first region and a second region, wherein the second region is located between the adjacent first regions;
a fin, disposed on the substrate, wherein the fin located in the second region includes a heavily doped region;
a gate structure, disposed on the fin and located in the first region;
a single diffusion break (SDB) structure, disposed on the fin and located in the second region; and
a capacitor gate structure, disposed on the fin and located in the second region,
wherein the capacitor gate structure is disposed on the SDB structure.

2. The semiconductor device according to claim 1, wherein the capacitor gate structure partially overlaps the SDB structure.

3. The semiconductor device according to claim 1, wherein a top surface of the SDB structure is lower than a top surface of the fin.

4. The semiconductor device according to claim 1, further including:
a dummy source/drain region, disposed in the fin and located on both sides of the capacitor gate structure.

5. The semiconductor device according to claim 4, wherein the dummy source/drain region includes an epitaxial layer.

6. A manufacturing method of a semiconductor device, including:
forming a fin on a substrate, wherein the fin spans a first region and a second region of the substrate, and the second region is located between the adjacent first regions;
forming a single diffusion break (SDB) structure in the second region of the substrate, wherein an extension direction of the SDB structure is perpendicular to an extension direction of the fin, and the SDB structure spans the fin;
forming a heavily doped region in the fin located in the second region; and
respectively forming a gate structure and a capacitor gate structure on the fin located in the first region and the second region of the substrate,
wherein the capacitor gate structure is disposed on the SDB structure.

7. The manufacturing method of the semiconductor device according to claim 6, further including following steps after forming the gate structure and the capacitor gate structure:
respectively forming a source/drain region and a dummy source/drain region in the fin located in the first region and the second region of the substrate; and
respectively forming a first contact plug and a second contact plug on the capacitor gate structure and the dummy source/drain region.

8. The manufacturing method of the semiconductor device according to claim 6, wherein forming the SDB structure includes:
perform an etching process on the fin and the substrate located in the second region to form a groove in the substrate; and
forming a dielectric layer in the groove,
wherein a top surface of the SDB structure is lower than a top surface of the fin.

9. The manufacturing method of the semiconductor device according to claim 6, wherein forming the gate structure and the capacitor gate structure includes:
forming a dielectric layer on the substrate;
forming a gate material layer on the dielectric layer; and
removing a portion of the dielectric layer and a portion of the gate material layer, to form the gate structure including a gate dielectric layer and a gate in the first region of the substrate and the capacitor gate structure including a capacitor dielectric layer and a capacitor gate in the second region of the substrate.

10. The manufacturing method of the semiconductor device according to claim 6, wherein forming the heavily doped region in the fin located in the second region includes performing an ion implantation process and a rapid thermal processing.
